(19) United States
(12) Patent Application Publication
(10) Pub. No.: US 2026/0223441 A1
(43) Pub. Date: Jul. 30, 2026

(54) STACKED SEMICONDUCTOR DEVICE INCLUDING GATE ETCH STRUCTURE

(71) Applicant: SAMSUNG ELECTRONICS CO., LTD., Suwon-si (KR)

(72) Inventors: HyoJong SHIN, Mechanicville, NY (US); Young Gook PARK, Rensselaer, NY (US); Jinyoung LIM, Schenectady, NY (US); Kang-ill SEO, Springfield, VA (US)

(73) Assignee: SAMSUNG ELECTRONICS CO., LTD., Suwon-si (KR)

(21) Appl. No.: 19/264,246

(22) Filed: Jul. 9, 2025

Related U.S. Application Data
(60) Provisional application No. 63/751,074, filed on Jan. 29, 2025.

(51) Int. Cl. H10D 84/83; H01L 23/528; H10D 30/00; H10D 30/01; H10D 30/43; H10D 62/10; H10D 62/13; H10D 64/01; H10D 64/23; H10D 84/01

(52) U.S. Cl. CPC H10D 84/8311; H10D 30/43; H10D 30/502; H10D 62/102; H10D 62/116; H10D 62/121; H10D 62/151; H10D 64/256; H10D 84/8312; H10D 84/832; H10W 20/435; H10D 30/014; H10D 30/0191; H10D 64/017; H10D 84/0128; H10D 84/0151

(57) ABSTRACT

Provided is a semiconductor device which may include: a 1^{st} channel structure; a 1^{st} source/drain region on the 1^{st} channel structure, the 1^{st} source/drain region and the 1^{st} channel structure connected in a 1^{st} direction; a gate structure on the 1^{st} channel structure; and a 1^{st} gate-etch structure on the 1^{st} channel structure, the 1^{st} gate-etch structure comprising an insulation material, wherein the 1^{st} gate-etch structure is connected to the 1^{st} channel structure in a 2^{nd} direction intersecting the 1^{st} direction, and wherein the 1^{st} gate-etch structure does not extend beyond a length of the 1^{st} channel structure in the 1^{st} direction along a side surface of the 1^{st} source/drain region extending in the 1^{st} direction.

### CROSS-REFERENCE TO RELATED APPLICATION

This application is based on and claims priority from U.S. Provisional Application No. 63/751,074 filed on Jan. 29, 2025 in the U.S. Patent and Trademark Office, the disclosure of which is incorporated herein in its entirety by reference.

### BACKGROUND

### 1. Field

Apparatuses consistent with example embodiments of the disclosure relate to a semiconductor device including one or more gate etch structures.

### 2. Description of Related Art

A stacked field-effect transistor (FET) device has been introduced in response to increased demand for a semiconductor device having a high device density and performance. The stacked semiconductor device may include a 1^{st} FET at a 1^{st} level and a 2^{nd} FET at a 2^{nd} level above the 1^{st} level, where each of the two FETs may be a fin field-effect transistor (FinFET), a nanosheet transistor, a forksheet transistor, or any other types of FET. The stacked semiconductor device formed of the FinFETs, nanosheet transistors, or forksheet transistors may also be referred to as a three-dimensional stacked (3D-stacked) semiconductor device.

The FinFET has one or more fin structures, which are protruded from a substrate, as a channel structure and a gate structure surrounding at least three surfaces of each of the fin structures. The nanosheet transistor is characterized by one or more nanosheet channel layers, which are vertically stacked or arranged on a substrate, as a channel structure and a gate structure surrounding all four surfaces of each of the nanosheet channel layers. The nanosheet transistor is referred to as a gate-all-around (GAA) transistor or a multi-bridge channel field-effect transistor (MBCFET). The forksheet transistor is a combination of two nanosheet transistors with an isolation wall therebetween. In the forksheet transistor, nanosheet channel layers of each nanosheet transistor are formed at each side of the isolation wall and pass through a gate structure in parallel with the isolation wall.

In addition to the stacked semiconductor device, a backside power distribution network (BSPDN) structure formed at a back side of a semiconductor device has been introduced to address a heavy traffic of signal lines and power rails, high device density, and increased contact resistance between structural elements of the stacked semiconductor device at a front side of the semiconductor device. Here, the front side refers to a side where a transistor structure including a channel structure, a gate structure, and source/drain regions is formed with respect to a substrate of the semiconductor device, and the back side refers to a side opposite the front side. The BSPDN structure may include backside metal lines such as a buried power rail connected to a voltage source and a buried signal line connected to another circuit element. Further, the BSPDN structure may include backside contact plugs connecting active elements, such as source/drain regions, of the semiconductor device to the buried power rails or signal lines though the back side of the semiconductor device. In embodiments, the BSPDN structure may be more useful to the stacked semiconductor devices.

In the meantime, the stacked semiconductor device provides various challenges including difficulties in manufacturing and implementing a low-power device and a low-resistance/capacitance device because the stacked semiconductor device is formed in a high-aspect ratio in a very dense area.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

The disclosure provides a stacked semiconductor device in which one or more gate-etch structures are formed to reduce a size or volume of a gate structure and a lower channel structure to reduce at least capacitance between the gate structure and source/drain regions, and further, implement a low-power semiconductor device.

According to an aspect of the disclosure, there is provided a semiconductor device which may include a 1^{st} channel structure, a 1^{st} source/drain region on the 1^{st} channel structure, the 1^{st} source/drain region and the 1^{st} channel structure being connected in a 1^{st} direction, a gate structure on the 1^{st} channel structure, and a 1^{st} gate-etch structure on the 1^{st} channel structure. The 1^{st} gate-etch structure may include an insulation material. The 1^{st} gate-etch structure may be connected to the 1^{st} channel structure in a 2^{nd} direction intersecting the 1^{st} direction, and the 1^{st} gate-etch structure may not extend beyond a length of the 1^{st} channel structure in the 1^{st} direction along a side surface of the 1^{st} source/drain region extending in the 1^{st} direction.

According to an aspect of the disclosure, there is provided a semiconductor device which may include a 1^{st} channel structure, a 1^{st} source/drain region on the 1^{st} channel structure, the 1^{st} source/drain region and the 1^{st} channel structure being connected in a 1^{st} direction, a 1^{st} gate structure on the 1^{st} channel structure, and a 1^{st} gate-etch structure on the 1^{st} channel structure. The 1^{st} gate-etch structure may include an insulation material. The 1^{st} gate-etch structure may be connected to the 1^{st} channel structure in a 2^{nd} direction intersecting the 1^{st} direction, and a length of the 1^{st} gate-etch structure may be equal to a length of the 1^{st} gate structure in the 1^{st} direction.

According to an aspect of the disclosure, there is provided a semiconductor device which may include a 1^{st} gate structure and a 2^{nd} gate structure adjacent thereto in a 1^{st} direction, the 1^{st} gate structure and the 2^{nd} gate structure extending in a 2^{nd} direction that intersects the 1^{st} direction, a source/drain region between the 1^{st} gate structure and the 2^{nd} gate structure, and a gate-etch structure on the 1^{st} gate structure among the 1^{st} gate structure and the 2^{nd} gate structure, the gate-etch structure including an insulation material.

According to an aspect of the disclosure, there is provided a method of manufacturing a semiconductor device, which may include: forming a 1^{st} channel structure, forming a 1^{st} source/drain region on the 1^{st} channel structure such that the 1^{st} source/drain region and the 1^{st} channel structure are connected in a 1^{st} direction, forming a 1^{st} gate structure on the 1^{st} channel structure, and forming a 1^{st} gate-etch structure on the 1^{st} gate structure such that the 1^{st} gate-etch structure is connected to the 1^{st} channel structure in a 2^{nd} direction intersecting the 1^{st} direction, and the 1^{st} gate-etch structure does not extend beyond a length of the 1^{st} channel structure in the 1^{st} direction along a side surface of the 1^{st} source/drain region extending in the 1^{st} direction.

### BRIEF DESCRIPTION OF DRAWINGS

Example embodiments of the disclosure will be more clearly understood from the following detailed description taken in conjunction with the accompanying drawings.

FIGS. 1A-1D illustrate a stacked semiconductor device having different channel widths and different source/drain region widths, according to one or more embodiments.

FIGS. 2A-2D illustrate a stacked semiconductor device including a gate-etch structure, according to one or more embodiments.

FIGS. 3A-3D illustrate a stacked semiconductor device including gate-etch structures that vertically overlap, according to one or more embodiments.

FIGS. 4A-4D illustrate a stacked semiconductor device including gate-etch structures that do not vertically overlap, according to one or more other embodiments.

FIGS. 5A-5L illustrate intermediate semiconductor devices obtained after respective steps of manufacturing a stacked semiconductor device including gate-etch structures, according to one or more embodiments.

FIGS. 6A and 6B are a flowchart of manufacturing a stacked semiconductor device including gate-etch structures, according to one or more embodiments.

FIG. 7 is a schematic block diagram illustrating an electronic device including one or more stacked semiconductor devices including one or more gate-etch structures, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain region, a silicide layer such as cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

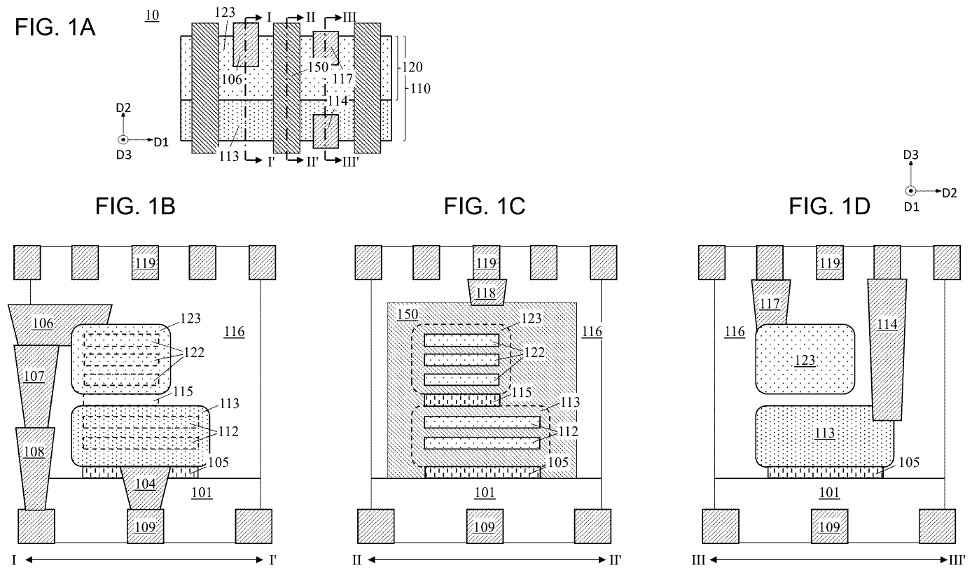

FIGS. 1A-1D illustrate a stacked semiconductor device having different channel widths and different source/drain region widths, according to one or more embodiments. FIG. 1A is a plan view of the stacked semiconductor device, and FIGS. 1B-1D are cross-section views of the stacked semiconductor device of FIG. 1A taken along lines I-I′, II-II′ and III-III′ shown in FIG. 1A, respectively.

It is to be understood that FIG. 1A shows only selected elements formed on a front side of the stacked semiconductor device such as active patterns including source/drain regions, source/drain contact structures, and gate structures, and thus, some structural elements such as metal lines formed vertically above or below of the active patterns are not shown therein for brevity purposes. Further, in order to assist better understanding of the stacked semiconductor devices, FIG. 1B also shows channel structures of the stacked semiconductor devices that can be seen at the cross-section view taken along line II-II′ using dashed lines, and FIG. 1C also shows source/drain regions of the stacked semiconductor device that can be seen at the cross-section view taken along line III-III′ using dashed lines.

Referring to FIGS. 1A-1D, a stacked semiconductor device 10 may include a 1^{st} active pattern 110 and a 2^{nd} active pattern 120 extending in a D1 direction. The 2^{nd} active pattern 120 may be stacked on the 1^{st} active pattern 110 formed on a backside isolation layer 101 in a D3 direction intersecting the D1 direction and the D2 direction, and partially overlap the 1^{st} active pattern 110 in the D3 direction. The 1^{st} active pattern 110 may be partially overlapped by the 2^{nd} active pattern 120 and may have a greater width than the 2^{nd} active pattern 120 in the D2 direction. In the stacked semiconductor device 10 may also be formed of a plurality of gate structures 150 arranged in the D1 direction and extending in the D2 direction across the active patterns 110 and 120.

The D1 direction refers to a channel-length direction in which a current flows between two source/drain regions connected to each other through a channel structure, the D2 direction is a channel-width direction or a cell-height direction, and the D3 direction is a channel-thickness direction. The D1 direction and the D2 direction may each be referred to as a horizontal direction and the D3 direction may be referred to as a vertical direction.

The backside isolation layer 101 may be formed by replacing a silicon (Si)-based substrate and include at least one backside contact plug 104 and a plurality of backside metal lines 109. The backside isolation layer 101 may be formed of a low-k material such as silicon oxide (e.g., SiO₂), not being limited thereto.

The stacked semiconductor device 10 may be formed of a 1^{st} field-effect transistor (FET), which is an n-type field-effect transistor (NFET) at a 1^{st} level or a lower stack, and a 2^{nd} FET, which is a p-type field-effect transistor (PFET) at a 2^{nd} level or an upper stack above the 1^{st} level in the D3 direction. The 1^{st} FET and the 2^{nd} FET may be formed based on the 1^{st} active pattern 110 and the 2^{nd} active pattern 120, respectively, along with a corresponding gate structure 150. However, the disclosure is not limited thereto. According to one or more other embodiments, each of the 1^{st} FET and the 2^{nd} FET may be of either p-type or n-type to form the stacked semiconductor device 10. Herebelow, it is assumed that the 1^{st} FET is an NFET and the 2^{nd} FET is a PFET.

The 1^{st} active pattern 110 for the 1^{st} FET may form a 1^{st} channel structure 112 and 1^{st} source/drain regions 113 at the 1^{st} level. The 1^{st} channel structure 112 may include a plurality of 1^{st} nanosheet layers epitaxially grown from a silicon-based substrate therebelow, and thus, the 1^{st} nanosheet layers may also be formed of silicon (Si). In the manufacturing the stacked semiconductor device 10, the silicon-based substrate may be entirely or partially replaced by the backside isolation layer 101. However, the stacked semiconductor device 10 may include a bottom diffusion isolation (BDI) layer 105 between the 1^{st} source/drain regions 113 and the silicon-base structures 112 which is formed to suppress current leakage from the 1^{st} source/drain regions 113 or the 1^{st} channel structure 112 to the silicon-based substrate or the backside isolation structure 101. The BDI layer 105 may be formed of an insulation material or a dielectric material such as SiBCN, SiCN, SiOC, SiOCN, Si₃N₄, etc.

The 1^{st} source/drain regions 113 of n-type may be epitaxially grown from the 1^{st} nanosheet layers of the 1^{st} channel structure 112, and may be formed of silicon doped with n-type impurities (e.g., phosphorus (P), arsenic (As), or antimony (Sb)). The 1^{st} channel structure 112 may be surrounded by a gate structure 150 which controls current flow between the 1^{st} source/drain regions 113 through the 1^{st} channel structure 112. The gate structure 150 may include a gate dielectric layer surrounding the 1^{st} nanosheet layers, a 1^{st} work-function metal layer formed on the gate dielectric layer, and a gate electrode formed on the 1^{st} work-function metal layer. Thus, the 1^{st} channel structure 112 including the 1^{st} nanosheet layers, the 1^{st} source/drain regions 113 and the gate structure 150 may form the 1^{st} FET as an NFET implemented by a nanosheet transistor at the 1^{st} level. The gate electrode of the gate structure 150 may be formed of a metal such as tungsten (W), copper (Cu), aluminum (Al), cobalt (Co), etc., or an alloy thereof, not being limited thereto.

The 2^{nd} active pattern 120 for the 2^{nd} FET may form a 2^{nd} channel structure 122 and 2^{nd} source/drain regions 123 at the 2^{nd} level. The 2^{nd} channel structure 122 may include a plurality of 2^{nd} nanosheet layers also epitaxially grown from the silicon-based substrate, and thus, the 2^{nd} nanosheet layers may also be formed of silicon. The 2^{nd} source/drain regions 123 may be epitaxially grown from the 2^{nd} nanosheet layers of the 2^{nd} channel structure 122, and may be formed of silicon germanium (SiGe) doped with p-type impurities (e.g., boron (B), gallium (Ga), or indium (In)). The 2^{nd} channel structure 122 may also be surrounded by the gate structure 150 which controls current flow between the 2^{nd} source/drain regions 123 through the 2^{nd} channel structure 122. The gate dielectric layer surrounding the 1^{st} channel structure 112 may extend to also surround the 2^{nd} channel structure 122, and a 2^{nd} work-function metal layer may be formed on the extended portion of the gate dielectric layer. Further, the gate electrode on the 1^{st} work-function metal layer may also extend to surround the 2^{nd} work-function metal layer. Thus, the 2^{nd} channel structure 122 including the 2^{nd} nanosheet layers, the 2^{nd} source/drain regions 123 and the gate structure 150 may form the 2^{nd} FET as a PFET implemented by a nanosheet transistor at the 2^{nd} level.

Herein, the 1^{st} nanosheet layers and the 2^{nd} nanosheet layers may also be respectively referred to as 1^{st} channel layers and 2^{nd} channel layers. The 1^{st} channel structure 112 including the 1^{st} nanosheet layers and the 2^{nd} channel structure 122 including the 2^{nd} nanosheet layers may be isolated from each other through a middle isolation layer 115 which may be formed of an insulation material or a dielectric material such as SiBCN, SiCN, SiOC, SiOCN, Si₃N₄, etc., similar to those forming the BDI layer 105, not being limited thereto

As described earlier, the 2^{nd} active pattern 120 has a smaller width than the 1^{st} active pattern 110 in the D2 direction. Accordingly, the 2^{nd} nanosheet layers forming the 2^{nd} channel structure 122 of the 2^{nd} FET may have a smaller width than the 1^{st} nanosheet layers forming the 1^{st} channel structure 112 of the 1^{st} FET in the D2 direction, and the 2^{nd} channel structure 122 may only partially overlap the 1^{st} channel structure 112 in the D3 direction.

For example, left side surfaces of the 2^{nd} nanosheet layers may be aligned or coplanar with left side surfaces of the 1^{st} nanosheet layers in the D3 direction, while right side surfaces of the 2^{nd} nanosheet layers are not aligned or coplanar with right side surfaces of the 1^{st} nanosheet layers in the D3 direction. Thus, the 2^{nd} source/drain regions 123 epitaxially grown from the 2^{nd} nanosheet layers may also be formed to have a smaller width than the 1^{st} source/drain regions 113 epitaxially grown from the 1^{st} nanosheet layers in the D2 direction. Accordingly, a right side surface of the 1^{st} source/drain region 113 may not be overlapped by the 2^{nd} source/drain region 123, while a left side surface of a 1^{st} source/drain region 113 may be overlapped by the 2^{nd} source/drain region 123. This width difference of the source/drain regions may provide a free space above a top surface of the 1^{st} source/drain region 113 which is not vertically overlapped by the 2^{nd} source/drain region 123 so that other circuit elements such as a frontside contact plug 114 may be vertically formed through this space to contact at least a portion of the top surface of the 1^{st} source/drain region 113.

A frontside isolation layer 116 may be formed on a front side of the semiconductor device 100 to isolate the stacked semiconductor device 10 from other semiconductor devices. The frontside isolation layer 116, like the backside isolation layer 101, may be formed of a low-k dielectric material such as silicon oxide (e.g., SiO₂), not being limited thereto.

On a back side of the semiconductor device 100 may be formed a BSPDN structure including at least one backside contact plug 104 and backside metal lines 109, as shown in FIG. 1B. The backside contact plug 104 may be formed on a bottom surface of one of the 1^{st} source/drain regions 113 of the 1^{st} FET, and may be connected to a backside metal line 109 buried in the backside isolation layer 101. The backside contact plug 104 may connect the 1^{st} source/drain region 113, which is of n-type, to a negative voltage source (VSS or ground) or another circuit element through the backside metal line 109. The backside contact plug 104 may take a form of a pillar as a via structure vertically connecting, for example, two metal lines extending in the D1 direction or D2 direction at different vertical levels in the D3 direction. In contrast, the backside metal line 109 may extend in the D1 direction beyond a length of the 1^{st} source/drain region 113 in the D1 direction. Also, one of the 2^{nd} source/drain regions 123 of the 2^{nd} FET may be connected to a backside metal line 109 through a frontside contact plug 106 and a couple of via structures 107 and 108. This backside metal line 109 may connect the 2^{nd} source/drain region 123 to a positive voltage source (VDD) or another circuit element.

The other 1^{st} source/drain region 113 of the 1^{st} FET and the other 2^{nd} source/drain region 123 of the 2^{nd} FET may be connected to respective voltage sources or other circuit elements through other frontside contact plugs 114, 117 and respective frontside metal lines 119, as shown in FIG. 1D. A gate contact plug 118 may be formed on the gate structure 150 to be connected to another frontside metal line 119 to receive a gate input signal for the stacked semiconductor device 10, as shown in FIG. 1C.

The backside contact plug 104, the via structures 107, 108, the frontside contact plugs 106, 114, 117 and the metal lines 109, 119 may be formed of the same metal or different metals, which may be, for example, tungsten (W), copper (Cu), aluminum (Al), molybdenum (Mo), ruthenium (Ru), etc., or an alloy thereof.

The foregoing structural characteristics of the channel structures and the source/drain regions may be provided to address increasing demands for a high device density and an improved device performance in a stacked semiconductor device. As the frontside contact plug 114 is formed on the top surface of the 1^{st} source/drain region 113 through the non-overlapped free space, the stacked semiconductor device 10 may achieve an area gain and have reduced contact resistance compared to a stacked semiconductor device in which a frontside contact plug is formed on a side surface or a bottom surface of a lower source/drain region (corresponding to the 1^{st} source/drain region 113) when the lower source/drain region and an upper source/drain region (corresponding to the 2^{nd} source/drain region 123) have the same width.

In the stacked semiconductor device 10, the 2^{nd} channel structure 122 forming the 2^{nd} FET may have a greater number of nanosheet layers than that of the 1^{st} channel structure 112 forming the 1^{st} FET such that the two FETs may have the same or substantially same effective channel width (W_{eff}). For example, the 2^{nd} channel structure 122 may have three nanosheet layers while the 1^{st} channel structure 112 have two nanosheet layers.

The different channel widths and the different number of nanosheet layers, that is, channel layers, may facilitate optimization of the stacked semiconductor device in terms of not only area gain for a high-density semiconductor device but also device performance such as current speed, work load distribution, power efficiency, contact resistance, capacitance, thermal control, structural stability, etc.

In the meantime, the above-described stacked semiconductor device 10 may be formed differently to further improve device performance and achieve a low-power semiconductor device as described below.

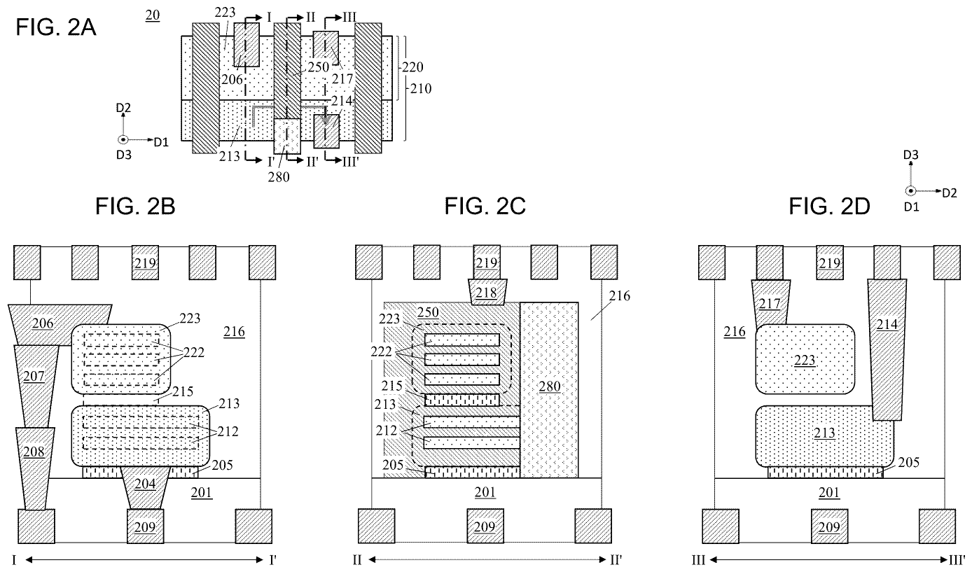

FIGS. 2A-2D illustrate a stacked semiconductor device including a gate-etch structure, according to one or more embodiments. FIG. 2A is a plan view of the stacked semiconductor device, and FIGS. 2B-2D are cross-section views of the stacked semiconductor device of FIG. 2A taken along lines I-I′, II-II′ and III-III′ shown in FIG. 2A, respectively.

Referring to FIGS. 2A-2D, which correspond to FIGS. 1A-1D, respectively, a stacked semiconductor device 20 may be formed of the same structural elements forming the stacked semiconductor device 10, and thus, duplicate descriptions thereof may be omitted herein. For example, a 1^{st} active pattern 210 including a 1^{st} channel structure 212 and 1^{st} source/drain regions 213, a 2^{nd} active pattern 220 including a 2^{nd} channel structure 222 and 2^{nd} source/drain regions 223, and gate structures 250 of the stacked semiconductor device 20 may be the same as corresponding structural elements of the stacked semiconductor device 10 of FIGS. 1A-1D. Further, the stacked semiconductor device 20 may include a backside isolation layer 201, a BDI layer 205, a middle isolation layer 215, a frontside isolation layer 216, backside metal lines 209, frontside metal lines 219, a backside contact plug 204, via structures 207, 208, frontside contact plugs 206, 214, 217, and a gate contact plug 218 which may be the same as corresponding structural elements of the stacked semiconductor device 10.

However, unlike the stacked semiconductor device 10, the stacked semiconductor device 20 may include a gate-etch structure 280 which may be formed of an insulation material or a dielectric material such as silicon nitride (e.g., Si₃N₄), not being limited thereto. The gate-etch structure 280 may be formed in a space provided by etching a right portion of the gate structure 250 and a right portion of the 1^{st} channel structure 212 surrounded by the right portion of the gate structure 250 in a region where the 1^{st} channel structure 212 is not overlapped by the 2^{nd} channel structure 222 in the D3 direction. Thus, as shown in FIG. 2B, a lower portion of the gate-etch structure 280 may contact the 1^{st} channel structure 212. For example, the lower portion of the gate-etch structure 280 may contact 1^{st} nanosheet layers forming the 1^{st} channel structure 212 to be connected thereto in the D2 direction.

The lower portion of the gate-etch structure 280 may also occupy a space provided by etching portions of inner spacers isolating the gate structure 250 from the 1^{st} source/drain regions 213 in the non-overlapping region. Thus, a length of the gate-etch structure 280 may be equal to a length of the gate structure 250 in the D1 direction, and the lower portion of the gate-etch structure 280 may contact the 1^{st} source/drain regions 213 to be connected thereto in the D1 direction. However, the gate-etch structure 280 may be formed not to extend beyond a length of the 1^{st} channel structure 212 in the D1 direction along side surfaces of the 1^{st} source/drain regions 213 extending in the D1 direction.

The gate-etch structure 280 may be formed to occupy a space provided by etching the right portion of the 1^{st} channel structure 212, and thus, the length of the gate-etch structure 280 may also be equal to the length of the 1^{st} channel structure 212 in the D1 direction, and two side surfaces of the gate-etch structure 280 opposite in the 1^{st} direction may be coplanar or aligned with two side surfaces of the 1^{st} channel structures 212, that is, each of the 1^{st} nanosheet layers, opposite in the 1^{st} direction and two side surfaces of the gate structure 250 opposite in the 1^{st} direction, respectively.

Further, the gate-etch structure 280 may be formed such that a right side surface of the 1^{st} channel structure 212, for example, a right side surface of each of the 1^{st} nanosheet layers forming the 1^{st} channel structure 212 contact the lower portion of the gate-etch structure 280. Thus, a channel width of the 1^{st} channel structure 212 may be reduced compared to that of the 1^{st} channel structure 112 of the stacked semiconductor device 10. Accordingly, an effective channel width (W_{eff}) of a 1^{st} FET of the stacked semiconductor device 20 may be reduced by the gate-etch structure 280. Also, a size of the gate structure 250 may also be reduced by the gate-etch structure 280. Therefore, power consumption of the stacked semiconductor device 20 may be reduced, thereby achieving a low-power semiconductor device. For example, as the width of the 1^{st} channel structure 212 is reduced to form a low-power NFET while the width of the 2^{nd} channel structure 222 is maintained for a high-power PFET, the stacked semiconductor device 20 may be used to implement a NOR gate. However, a width of each of the 1^{st} nanosheet layers may still be greater than a width of each of the 2^{nd} nanosheet layers in the D2 direction

As the gate-etch structure 280 is formed in the above-described manner, each of the 1^{st} nanosheet layers of the 1^{st} channel structure 212 may be surrounded by the gate structure 250 only at a top surface, a left side surface and a bottom surface, while each of the 2^{nd} nanosheet layers of the 2^{nd} channel structure 222 may be surrounded by the gate structure 250 at all four surfaces, that is, a top surface, a left side surface, a right side surface and a bottom surface.

The gate-etch structure 280 may be formed in the non-overlapping region such that at least a portion of the gate structure 250 is formed between an upper portion of the gate-etch structure 280 and the 2^{nd} channel structure 222 including the 2^{nd} nanosheet layers in the D2 direction. This at least a portion of the gate structure 250 may include a portion of a gate electrode of the gate structure 250 and/or a portion of a 2^{nd} work-function metal layer of the gate structure 250. However, at least another portion of the gate structure 250 at a right side of the 2^{nd} channel structure 222 may be removed, and thus, capacitance generated between the gate structure 250 and the adjacent source/drain regions 213 and 223 may be reduced to contribute performance improvement of the stacked semiconductor device 20.

The gate-etch structure 280 may be formed in a space provided by etching the right side portion of the gate structure 250 from top to bottom, and thus, a top surface and a bottom surface of the gate-etch structure 280 may be horizontally coplanar or aligned with a top surface and a bottom surface of the gate structure 250.

The formation of the gate-etch structure 280 as described above does not limit the disclosure.

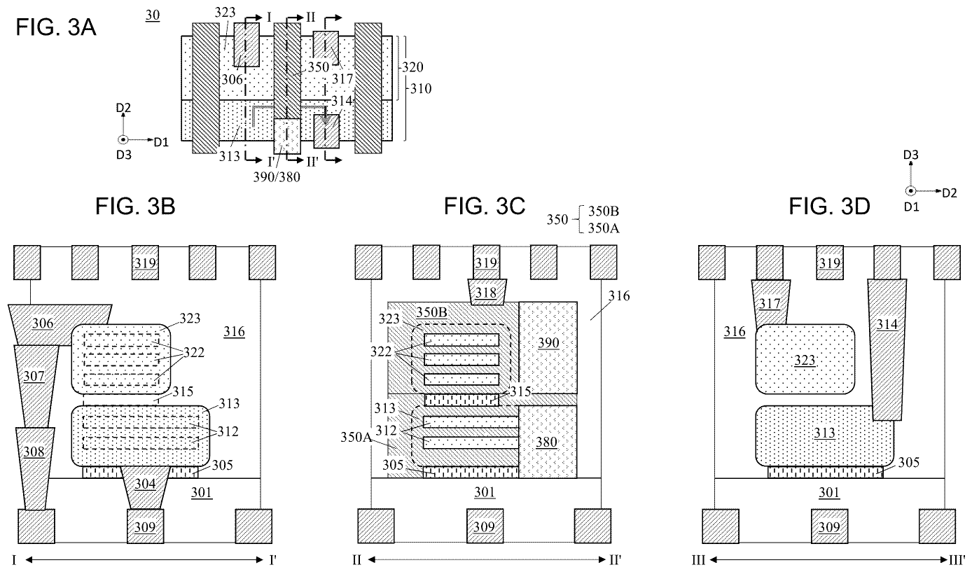

FIGS. 3A-3D illustrate a stacked semiconductor device including gate-etch structures that vertically overlap, according to one or more embodiments. FIG. 3A is a plan view of the stacked semiconductor device, and FIGS. 3B-3D are cross-section views of the stacked semiconductor device of FIG. 3A taken along lines I-I′, II-II′ and III-III′ shown in FIG. 3A, respectively.

Referring to FIGS. 3A-3D, which correspond to FIGS. 2A-2D, respectively, a stacked semiconductor device 30 may be formed of the same or similar structural elements forming the stacked semiconductor device 20, and thus, duplicate descriptions thereof may be omitted herein. For example, a 1^{st} active pattern 310 including a 1^{st} channel structure 312 and 1^{st} source/drain regions 313 and a 2^{nd} active pattern 320 including a 2^{nd} channel structure 322 and 2^{nd} source/drain regions 323 of the stacked semiconductor device 30 may be the same as corresponding structural elements of the stacked semiconductor device 20 of FIGS. 2A-2D. Further, the stacked semiconductor device 30 may include a backside isolation layer 301, a BDI layer 305, a middle isolation layer 315, a frontside isolation layer 316, backside metal lines 309, frontside metal lines 319, a backside contact plug 304, via structures 307, 308, frontside contact plugs 306, 314, 317, and a gate contact plug 318 which may be the same as corresponding structural elements of the stacked semiconductor device 20.

However, while the stacked semiconductor device 20 includes the gate structure 250 formed of a single piece gate electrode surrounding both a 1^{st} work-function metal layer on the 1^{st} channel structure 212 and a 2^{nd} work-function metal layer on the 2^{nd} channel structure 222, the stacked semiconductor device 30 may include the 1^{st} gate structure 350A and the 2^{nd} gate structure 350B formed at different steps, for example, a backside process and a frontside process, respectively. The 1^{st} gate structure 350A may include a 1^{st} gate dielectric layer surrounding the 1^{st} nanosheet layers, a 1^{st} work-function metal layer on the 1^{st} gate dielectric layer, and a 1^{st} gate electrode on the 1^{st} work-function metal layer, and the 2^{nd} gate structure 350B may include a 2^{nd} gate dielectric layer surrounding the 2^{nd} nanosheet layers, a 2^{nd} work-function metal layer on the 2^{nd} gate dielectric layer, and a 2^{nd} gate electrode on the 2^{nd} work-function metal layer.

The 1^{st} gate electrode and the 2^{nd} gate electrode may be formed of the same metal or metal alloy and may be connected to each other to form the two gate structures 350A and 350B as a common gate structure 350. Still, however, there may be formed a connection surface, an interface, or a junction between the two gate electrodes of the two gate structures 350A and 350B in a case where the two gate structures 350A and 350B are formed at different steps and times.

Further, while the stacked semiconductor device 20 includes the gate-etch structure 280 formed in the space provided by etching the right side portion of the gate structure 250 from top to bottom, the stacked semiconductor device 30 may include a 1^{st} gate-etch structure 380 and a 2^{nd} gate-etch structure 390 formed in spaces provided by etching a right side portion of the 1^{st} gate structure 350A at a 1^{st} level and a right side portion of the 2^{nd} gate structure 350B at a 2^{nd} level of the stacked semiconductor device 30, respectively.

While the gate-etch structure 280 of the stacked semiconductor device 20 is a single-piece isolation structure formed by a single deposition step, the gate-etch structures 380 and 390 may be two different, separated isolation structures formed by etching the two gate structures 350A and 350B at two different steps although the 2^{nd} gate-etch structure 390 may overlap the 1^{st} gate-etch structure 380 in the D3 direction. The two gate-etch structures 380 and 390 may be formed of the same insulation material or dielectric material forming the gate-etch structure 280, or different insulation materials or dielectric materials.

Although the 1^{st} gate-etch structure 380 is separated from the 2^{nd} gate-etch structure 390, the 1^{st} gate-etch structure 380 and the 2^{nd} gate-etch structure 390 may have similar structural shapes as the lower portion and the upper portion of the gate-etch structure 280 of the stacked semiconductor device 20, respectively.

For example, a bottom surface of the 1^{st} gate-etch structure 380 may be horizontally coplanar or aligned with a bottom surface of the 1^{st} gate structure 350A, and a top surface of the 2^{nd} gate-etch structure 390 may be horizontally coplanar or aligned with a top surface of the 2^{nd} gate structure 350B. Further, a top surface of the 1^{st} gate-etch structure 380 may be formed at a level above a top surface of the 1^{st} channel structure 312, for example, a top surface of the uppermost 1^{st} nanosheet layer of the 1^{st} channel structure 312, and a bottom surface of the 2^{nd} gate-etch structure 390 may be formed at a level below a bottom surface of the 2^{nd} channel structure, for example, a bottom surface of the lowermost 2^{nd} nanosheet layer of the 2^{nd} channel structure 322.

The 1^{st} gate-etch structure 380 may contact the 1^{st} channel structure 312. For example, the 1^{st} gate-etch structure 380 may contact the 1^{st} nanosheet layers forming the 1^{st} channel structure 312 to be connected thereto in the D2 direction.

The 1^{st} gate-etch structure 380 may also occupy a space provided by etching portions of inner spacers isolating the gate structure 350 from the 1^{st} source/drain regions 313 in a non-overlapping region where the 1^{st} channel structure 312 is not overlapped by the 2^{nd} channel structures 322 in the D3 direction. Thus, a length of the 1^{st} gate-etch structure 380 may be equal to a length of the 1^{st} gate structure 350A in the D1 direction, and the 1^{st} gate-etch structure 380 may contact the 1^{st} source/drain regions 313 to be connected thereto in the D1 direction. Also, a length of the 2^{nd} gate-etch structure 390 may be equal to a length of the 2^{nd} gate structure 350B, which may also be equal to a length of the 1^{st} gate structure 350A in the D1 direction. However, the 1^{st} gate-etch structure 380 may be formed not to extend beyond a length of the 1^{st} channel structure 312 in the D1 direction along side surfaces of the 1^{st} source/drain regions 313 extending in the D1 direction.

The 1^{st} gate-etch structure 380 may formed to occupy a space provided by etching a right portion of the 1^{st} channel structure 312, and thus, the length of the 1^{st} gate-etch structure 380 may also be equal to the length of the 1^{st} channel structure 312 in the D1 direction. Thus, in the stacked semiconductor device 30, the gate structures 350A, 350B, the gate-etch structures 380, 390, and the channel structures 312, 322 may have an equal length in the D1 direction.

In addition, two side surfaces of the 1^{st} gate-etch structure 380 opposite in the 1^{st} direction may be coplanar or aligned with two side surfaces of the 1^{st} channel structures 312, that is, each of the 1^{st} nanosheet layers, opposite in the 1^{st} direction, two side surfaces of the 1^{st} gate structure 350A opposite in the 1^{st} direction, two side surfaces of the 2^{nd} gate-etch structure 390 opposite in the 1^{st} direction, two side surfaces of the 2^{nd} gate structure 350B opposite in the 1^{st} direction, and two side surfaces of the 2^{nd} channel structures 322, that is, each of the 2^{nd} nanosheet layers, opposite in the 1^{st} direction, respectively.

Further, the 1^{st} gate-etch structure 380 may be formed such that a right side surface of the 1^{st} channel structure 312, for example, a right side surface of each of the 1^{st} nanosheet layers forming the 1^{st} channel structure 312 contacts the 1^{st} gate-etch structure 380. Thus, a channel width of the 1^{st} channel structure 312 may be reduced compared to that of the 1^{st} channel structure 112 of the stacked semiconductor device 10. Accordingly, an effective channel width (W_{eff}) of a 1^{st} FET of the stacked semiconductor device 30 may be reduced by the 1^{st} gate-etch structure 380. Also, a size of the gate structure 350 may also be reduced by the 1^{st} gate-etch structure 380. Therefore, power consumption of the stacked semiconductor device 30 may be reduced, thereby achieving a low-power semiconductor device. However, a width of each of the 1^{st} nanosheet layers may still be greater than a width of each of the 2^{nd} nanosheet layers in the D2 direction.

As the gate-etch structures 380 and 390 are formed in the above-described manner, each of the 1^{st} nanosheet layers of the 1^{st} channel structure 312 may be surrounded by the 1^{st} gate structure 350A only at a top surface, a left side surface and a bottom surface, while each of the 2^{nd} nanosheet layers of the 2^{nd} channel structure 322 may be surrounded by the 2^{nd} gate structure 350B at all four surfaces, that is, a top surface, a left side surface, a right side surface and a bottom surface.

The 2^{nd} gate-etch structure 390 may be formed in the non-overlapping region such that at least a portion of the 2^{nd} gate structure 350B may be formed between the 2^{nd} gate-etch structure 390 and the 2^{nd} channel structure 322 including the 2^{nd} nanosheet layers in the D2 direction. This at least a portion of the 2^{nd} gate structure 350B may include a portion of the 2^{nd} gate electrode and/or a portion of the 2^{nd} work-function metal layer. However, as at least another portion of the 2^{nd} gate structure 350B at a right side of the 2^{nd} channel structure 322 is removed, capacitance generated between the 2^{nd} gate structure 350B and the adjacent source/drain regions 313 and 323 may be reduced to contribute improvement of device performance.

Although, the 1^{st} gate-etch structure 380 and the 2^{nd} gate-etch structure 390 are formed to be separated from each other in the stacked semiconductor device 30 as these two isolation structures are formed at two different steps, for example, a backside process and a frontside process, the two gate-etch structure 380 and 390 may be formed to be connected to each other in the D3 direction to have the same shape as the gate-etch structure 280 of the stacked semiconductor device 20.

The formation of the gate-etch structures 380 and 390 as described above does not limit the disclosure.

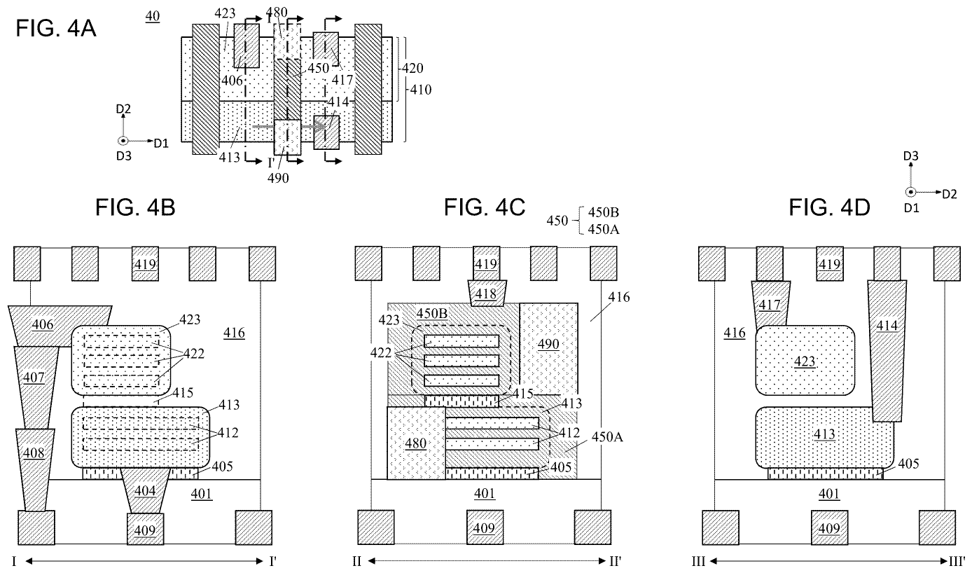

FIGS. 4A-4D illustrate a stacked semiconductor device including gate-etch structures that vertically do not overlap, according to one or more other embodiments. FIG. 4A is a plan view of the stacked semiconductor device, and FIGS. 4B-4D are cross-section views of the stacked semiconductor device of FIG. 4A taken along lines I-I′, II-II′ and III-III′ shown in FIG. 4A, respectively.

Referring to FIGS. 4A-4D, which correspond to FIGS. 3A-3D, respectively, a stacked semiconductor device 40 may be formed of the same or similar structural elements forming the stacked semiconductor device 30, and thus, duplicate descriptions thereof may be omitted herein. For example, a 1^{st} active pattern 410 including a 1^{st} channel structure 412 and 1^{st} source/drain regions 413, a 2^{nd} active pattern 420 including a 2^{nd} channel structure 422 and 2^{nd} source/drain regions 423, and a gate structure 450 including a 1^{st} gate structure 450A and a 2^{nd} gate structure 450B of the stacked semiconductor device 40 may be the same as corresponding structural elements of the stacked semiconductor device 30 of FIGS. 3A-3D. Further, the stacked semiconductor device 40 may include a backside isolation layer 401, a BDI layer 405, a middle isolation layer 415, a frontside isolation layer 416, backside metal lines 409, frontside metal lines 419, a backside contact plug 404, via structures 407, 408, frontside contact plugs 406, 414, 417, and a gate contact plug 418 which may be the same as corresponding structural elements of the stacked semiconductor device 30.

However, while the stacked semiconductor device 30 includes the 1^{st} gate-etch structure 380 at a right side of the 1^{st} gate structure 350A as the 2^{nd} gate-etch structure 390, the stacked semiconductor device 40 may include a 1^{st} gate-etch structure 480 at a left side of the 1^{st} gate structure 450A and a 2^{nd} gate-etch structure 490 at a right side of the 2^{nd} gate structure 450B although the two isolation structures are respectively formed a 1^{st} level and a 2^{nd} level of the stacked semiconductor device 40. The 1^{st} gate-etch structure 480 may be formed in a space provided by etching a left portion of the 1^{st} gate structure 450A at a 1^{st} level while a 2^{nd} gate-etch structure 490 may be formed in a space provided by etching a right portion of the 2^{nd} gate structure 450B at a 2^{nd} level. Still, the two gate-etch structures 480 and 490 may be formed of the same insulation materials or dielectric materials forming the gate-etch structures 380 and 390, respectively.

The 2^{nd} gate-etch structure 490 may be formed at the same position where the 1^{st} gate-etch structure 390 is formed and may be formed in the same manner, and thus, description thereof may be omitted herein. However, the 1^{st} gate-etch structure 480 may be formed at an opposite position to the 1^{st} gate-etch structure 380 of the stacked semiconductor device 30. Thus, the 1^{st} gate-etch structure 480 may contact a left side surface of the 1^{st} channel structure 412, for example, a left side surface of each of the 1^{st} nanosheet layers of the 1^{st} channel structure 412. Further, as shown in FIG. 4C, a left side surface of the 2^{nd} gate structure 450B may be vertically coplanar or aligned with a left side surface of the 1^{st} gate-etch structure 480, and a right portion of the 1^{st} gate-etch structure 480 may be overlapped by the 2^{nd} channel structure 422 in the D3 direction.

Still, a bottom surface of the 1^{st} gate-etch structure 480 may be horizontally coplanar or aligned with a bottom surface of the 1^{st} gate structure 450A, and a top surface of the 1^{st} gate-etch structure 480 may be formed at a level above a top surface of the 1^{st} channel structure 412, for example, a top surface of the uppermost 1^{st} nanosheet layer of the 1^{st} channel structure 412.

The 1^{st} gate-etch structure 480 may also occupy a space provided by etching portions of inner spacers isolating the gate structure 450 from the 1^{st} source/drain regions 413 in an overlapping region where the 1^{st} channel structure 412 is overlapped by the 2^{nd} channel structures 422 in the D3 direction. Thus, a length of the 1^{st} gate-etch structure 480 may be equal to a length of the 1^{st} gate structure 450A in the D1 direction, and the 1^{st} gate-etch structure 480 may contact the 1^{st} source/drain regions 413 to be connected thereto in the D1 direction. Also, a length of the 2^{nd} gate-etch structure 490 may be equal to a length of the 2^{nd} gate structure 450B, which may also be equal to a length of the 1^{st} gate structure 450A in the D1 direction. However, the 1^{st} gate-etch structure 480 may be formed not to extend beyond a length of the 1^{st} channel structure 412 in the D1 direction along side surfaces of the 1^{st} source/drain regions 413 extending in the D1 direction.

The 1^{st} gate-etch structure 480 may be formed to occupy a space provided by etching a left portion of the 1^{st} channel structure 412, and thus, the length of the 1^{st} gate-etch structure 480 may also be equal to the length of the 1^{st} channel structure 412 in the D1 direction. Thus, in the stacked semiconductor device 40, the gate structures 450A, 450B, the gate-etch structures 480, 490, and the channel structures 412, 422 may have an equal length in the D1 direction.

In addition, two side surfaces of the 1^{st} gate-etch structure 480 opposite in the 1^{st} direction may be coplanar or aligned with two side surfaces of the 1^{st} channel structures 412, that is, each of the 1^{st} nanosheet layers, opposite in the 1^{st} direction, two side surfaces of the 1^{st} gate structure 450A opposite in the 1^{st} direction, two side surfaces of the 2^{nd} gate-etch structure 490 opposite in the 1^{st} direction, two side surfaces of the 2^{nd} gate structure 450B opposite in the 1^{st} direction, and two side surfaces of the 2^{nd} channel structures 422, that is, each of the 2^{nd} nanosheet layers, opposite in the 1^{st} direction, respectively.

Further, the 1^{st} gate-etch structure 480 may be formed such that a left side surface of the 1^{st} channel structure 412, for example, a left side surface of each of the 1^{st} nanosheet layers forming the 1^{st} channel structure 412 contact the 1^{st} gate-etch structure 480. Thus, a channel width of the 1^{st} channel structure 412 may be reduced compared to that of the 1^{st} channel structure 112 of the stacked semiconductor device 10. Accordingly, an effective channel width (W_{eff}) of a 1^{st} FET of the stacked semiconductor device 40 may be reduced by the 1^{st} gate-etch structure 480. Also, a size of a gate structure 450 formed of the 1^{st} gate structure 450A and a size of the 2^{nd} gate structure 450B may also be reduced by the 1^{st} gate-etch structure 480 and the 2^{nd} gate-etch structure 490, respectively. Therefore, power consumption of the stacked semiconductor device 40 may be reduced, thereby achieving a low-power semiconductor device. However, a width of each of the 1^{st} nanosheet layers may still be greater than a width of each of the 2^{nd} nanosheet layers in the D2 direction.

As the gate-etch structures 480 and 490 are formed in the above-described manner, each of the 1^{st} nanosheet layers of the 1^{st} channel structure 412 may be surrounded by the 1^{st} gate structure 450A only at a top surface, a right side surface and a bottom surface, while each of the 2^{nd} nanosheet layers of the 2^{nd} channel structure 422 may be surrounded by the 2^{nd} gate structure 450B at all four surfaces, that is, a top surface, a left side surface, a right side surface and a bottom surface.

In the meantime, the formation of the 1^{st} gate-etch structure 480 at a left side of the 1^{st} channel structure 412 in the stacked semiconductor device 40 as shown in FIGS. 4A and 4C may facilitate reduction of channel resistance or diffusion resistance compared to the stacked semiconductor device 30 in which the 1^{st} gate-etch structure 380 is at a right side of the 1^{st} channel structures 312 and the stacked semiconductor device 20 in which a lower portion of the gate-etch structure 280 is at a right side of the 1^{st} channel structures 212. This is because, as indicated by respective arrows shown in FIGS. 2A, 3A and 4A, a current path between a 1^{st} source/drain regions 413 and the frontside contact plug 414 formed on the other 1^{st} source/drain region 413 in the stacked semiconductor device 40 can be shorter than a current path between a 1^{st} source/drain regions 313 and the frontside contact plug 314 formed on the other 1^{st} source/drain region 313 in the stacked semiconductor device 30, and a current path between a 1^{st} source/drain regions 213 and the frontside contact plug 214 formed on the other 1^{st} source/drain region 213 in the stacked semiconductor device 20.

For example, in the stacked semiconductor device 30, the 1^{st} gate-etch structure 380 contacting the 1^{st} source/drain region 313 may enforce some of carriers from a right portion (in the D2 direction) of the 1^{st} source/drain region 313 to detour the 1^{st} gate-etch structure 380 to reach the frontside contact plug 314 as indicated by the arrow shown in FIG. 3A because the 1^{st} gate-etch structure 380 and the frontside contact plug 314 are formed respectively at the right side (in the D2 direction) of the 1^{st} channel structure 312 and a right side (in the D2 direction) of the other 1^{st} source/drain region 313 on which the frontside contact plug 314 is formed (FIG. 3D). In contrast, in the stacked semiconductor device 40, some carriers from a right portion of the 1^{st} source/drain region 413 can move straight to the frontside contact plug 414 without being blocked by the 1^{st} gate-etch structure 480 as indicated by the arrow shown in FIG. 4A. This is because the 1^{st} gate-etch structure 480 is formed at the left side of the 1^{st} channel structure 412 while the frontside contact plug 414 is formed at a right side of the other 1^{st} source/drain region 413.

Provided herebelow is a method of manufacturing a stacked semiconductor device including gate-etch structures, according to one or more embodiments.

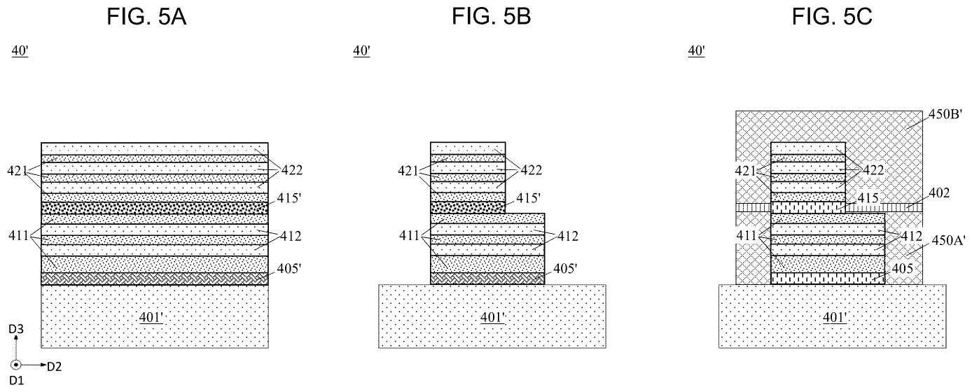

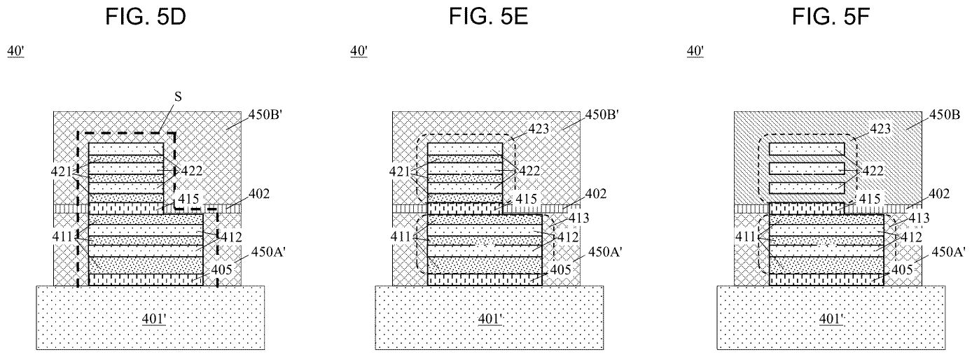

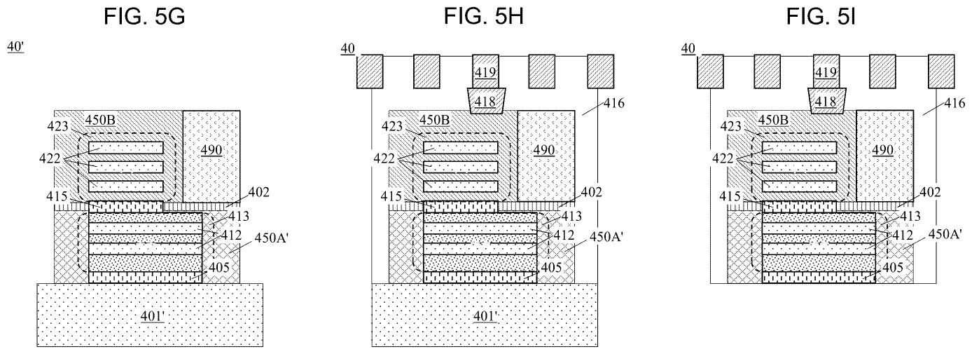

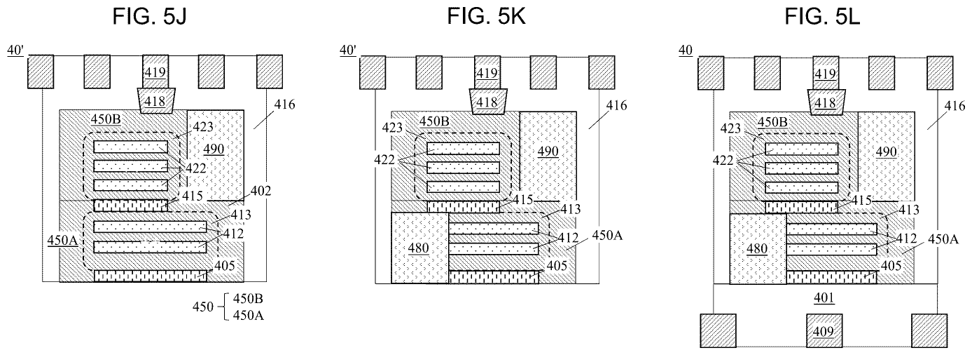

FIGS. 5A-5L illustrate intermediate semiconductor devices obtained after respective steps of manufacturing a stacked semiconductor device including gate-etch structures, according to one or more embodiments.

The stacked semiconductor device manufactured through the steps described herebelow in reference to FIGS. 5A-5L may be the same as the stacked semiconductor device 40 shown in FIGS. 4A-4D. Thus, duplicate descriptions, including those about materials and structures, thereof may be omitted and the same reference numerals may be used in FIGS. 5A-5L and the descriptions thereof. It is to be understood here that FIGS. 5A-5L are cross-section views corresponding to FIG. 4C, and thus, description of forming structural elements shown in FIGS. 4B and 4D may be omitted.

Referring to FIG. 5A, an intermediate semiconductor device 40′ may be formed by epitaxially growing a plurality of semiconductor layers, also referred to as nanosheet layers, on a substrate 401′.

The semiconductor layers may be epitaxially grown from the substrate 401′ in the order of a 1^{st} channel stack (lower channel stack) including a bottom sacrificial layer 405′, 1^{st} sacrificial layers 411 and 1^{st} channel layers 412 vertically stacked in an alternating manner, a middle sacrificial layer 415′, and a 2^{nd} channel stack (upper channel stack) including 2^{nd} sacrificial layers 421 and 2^{nd} channel layers 422 vertically stacked in an alternating manner on the middle sacrificial layer 415′. The 1^{st} channel layers 412 and the 2^{nd} channel layers 422 described herein in reference to FIGS. 5A-5L may be respectively referred to as a 1^{st} channel structure 412 including 1^{st} nanosheet layers and a 2^{nd} channel structure 422 including 2^{nd} nanosheet layers as described in reference to FIGS. 4A-4D.

While the substrate 401′ and the channel layers 412 and 422 are formed of silicon (Si), the sacrificial layers 405′, 411, 415′ and 421 may be formed of silicon germanium (SiGe) with respective Ge concentrations therein. The bottom sacrificial layer 405′ and the middle sacrificial layer 415′ may have a higher Ge concentration than the 1^{st} and 2^{nd} sacrificial layers 411 and 421. For example, the middle sacrificial layer 415′ may have a Ge concentration of 40-45%, and the 1^{st} and 2^{nd} sacrificial layers 411 and 421 may have a Ge concentration of 25-30%.

Referring to FIG. 5B, the intermediate semiconductor device 40′ may be patterned such that the 2^{nd} channel stack thereof formed of the 2^{nd} sacrificial layers 421, the 2^{nd} channel layer 422 and the middle sacrificial layer 415′ has a smaller width than the 1^{st} channel stack thereof formed of the bottom sacrificial layer 405′, the 1^{st} sacrificial layers 411 and the 1^{st} channel layers 412 in the D2 direction.

The patterning of the intermediate semiconductor device 40′ in this step may be performed such that the 1^{st} channel stack is partially overlapped by the 2^{nd} channel stack in the D3 direction. For example, the patterning may be performed such that left side surfaces of the 1^{st} channel stack, the middle sacrificial layer 415′ and the 2^{nd} channel stack are vertically aligned or coplanar with each other while a right portion of the 1^{st} channel stack is not vertically overlapped by the 2^{nd} channel stack, forming a non-overlapping region thereabove. Here, the 1^{st} channel stack and the 2^{nd} channel stack of the intermediate semiconductor device 40′ may form the 1^{st} active pattern 410 and the 2^{nd} active pattern 420 shown in FIG. 4A, respectively.

The patterning of the intermediate semiconductor device 40′ in this step may be performed through, for example, drying etching, for example, reactive ion etching (RIE), not being limited thereto.

Referring to FIG. 5C, a 1^{st} dummy gate structure 450A′ and a 2^{nd} dummy gate structure 450B′ with a dummy separation layer 402 therebetween may be formed to surround the 1^{st} channel stack and the 2^{nd} channel stack, respectively, and further, the bottom sacrificial layer 405′and the middle sacrificial layer 415′ may be removed and replaced by a BDI layer 405 and a middle isolation layer 415, respectively.

The 1^{st} dummy gate structure 450A′ may be formed to surround the 1^{st} channel stack through, for example, chemical vapor deposition (CVD), plasma enhanced chemical vapor deposition (PECVD), physical vapor deposition (PVD), ALD, PEALD or a combination thereof of polysilicon (p-Si) or amorphous silicon (a-Si), followed by planarization, for example, a chemical-mechanical polishing (CMP) operation, not being limited thereto.

Subsequently, the dummy separation layer 402 including an isolation material such as SiBCN, SiCN, SiOC, SiOCN, SiN, Si₃N₄, etc., may be formed through, for example, ALD or PEALD at a level of the middle sacrificial layer 415′ to isolate the 1^{st} dummy gate structure 450A′ from a 2^{nd} dummy gate structure 450B′ to be formed at a next step. Here, the dummy separation layer 402 may be formed of an isolation material such as as SiBCN, SiCN, SiOC, SiOCN, SiN, Si₃N₄, etc.

The 2^{nd} dummy gate structure 450B′ may be formed in the same or similar manner as the formation of the 1^{st} dummy gate structure 450A′ using the same material as the that forming the 1^{st} dummy gate structure 450A′ to surround the 2^{nd} channel stack of the intermediate semiconductor device 40′.

Further, the bottom sacrificial layer 405′ and the middle sacrificial layer 415′ may be removed and replaced by the BDI layer 405 and the middle isolation layer 415, respectively. The removal of the bottom isolation layer 405′ and the middle sacrificial layer 415′ may be performed through, for example, wet etching using an etchant such as an ammonia-peroxide mixture which removes the BDI layer 405′ and the middle sacrificial layer 415′ of SiGe with a high Ge concentration while the channel layers 412 and 422 of silicon (Si) and the sacrificial layers 411 and 421 of SiGe with a low Ge concentration are not or minimally attacked by the etchant. Subsequently, an isolation material such as SiBCN, SiCN, SiOC, SiOCN, SiN, Si₃N₄, etc., may fill in spaces from which the BDI layer 405 and the middle sacrificial layer 415′ are removed, thereby forming the BDI layer 405 and the middle isolation layer 415. The formation of the BDI layer 405 and the middle isolation layer 415 may be performed through, for example, atomic layer deposition (ALD) or plasma-enhanced ALD (PEALD), not being limited thereto. The BDI layer 405 and the middle isolation layer 415 may be formed of isolation materials that are the same as or different from the materials forming the dummy separation layer 402.

The BDI layer 405 may be formed to suppress current leakage from the 1^{st} channel structure 412 and 1^{st} source/drain regions 413 to be formed from the 1^{st} channel structures 412. The middle isolation layer 415 may be formed to isolate a 1^{st} channel structure 412 and a 2^{nd} channel structure 422 to be respectively formed from the 1^{st} channel stack and the 2^{nd} channel stack of the intermediate semiconductor device 40′.

Referring to FIG. 5D, the intermediate semiconductor device 40′ may be patterned to form spaces where 1^{st} source/drain regions 413 and 2^{nd} source/drain regions 423 thereabove are to be formed.

In this step, the 2^{nd} channel stack and the 1^{st} channel stack, that is, the 2^{nd} active pattern 420 and the 1^{st} active pattern 410 therebelow as shown in FIG. 4A may be patterned through, for example, dry etching or wet etching between the gate structures 450 as shown in FIG. 4A to form therein spaces S (indicated by a dashed line in FIG. 5D) in which the 1^{st} source/drain regions 413 and the 2^{nd} source/drain regions 423 are to be formed in a next step.

Subsequent to the patterning of the 2^{nd} channel stack and the 1^{st} channel stack, the substrate 401′ exposed below the spaces S formed by this patterning operation may also be patterned to form a placeholder recess and a placeholder structure therein. The placeholder structure may be formed to reserve a space where a backside contact plug 404 (FIG. 4B) connected to a bottom surface of one of the 1^{st} source/drain regions 413 is to be formed in the next step. The patterning operations to form the spaces S and the placeholder recess may be performed through, for example, dry etching or wet etching. The placeholder structure may be epitaxially grown from the substrate 401′ forming inner surfaces of the placeholder recess. The placeholder structure may be formed of silicon germanium (SiGe).

Referring to FIG. 5E, the 1^{st} source/drain regions 413 and the 2^{nd} source/drain regions 423 may be formed in the spaces S obtained by the patterning of the 1^{st} channel stack and the 2^{nd} channel stack of the intermediate semiconductor device 40′ in the previous step (FIG. 5D).

The 1^{st} source/drain region 413 may be epitaxially grown from the 1^{st} channel layers 412 of the 1^{st} channel stack while the 1^{st} sacrificial layers 411 are covered by inner spacers formed at side surfaces thereof in the D1 direction, and the 2^{nd} source/drain regions 423 may be epitaxially grown from the 2^{nd} channel layers 422 of the 2^{nd} channel stack while the 2^{nd} sacrificial layers 421 are covered by inner spacers formed at side surfaces thereof in the D1 direction. When the epitaxial growth of the source/drain regions 413 and 423 is performed, n-type impurities such as phosphorus (P), arsenic (As), antimony (Sb), etc. may be in-situ doped in the epitaxial structure for the 1^{st} source/drain regions 413, and p-type impurities such as boron (B), gallium (Ga), or indium (In), etc. may be in-situ doped in the epitaxial structure for the 2^{nd} source/drain region 423.

Referring to FIG. 5F, the 2^{nd} dummy gate structure 450B′ and the 2^{nd} sacrificial layers 421 may be removed and replaced by a 2^{nd} gate structure 450B so that the 2^{nd} channel layers 422 are surrounded by the 2^{nd} gate structure 450B.

The 2^{nd} dummy gate structure 450B′ and the 2^{nd} sacrificial layers 421 may be removed through, for example, dry or wet etching, not being limited thereto, to release the 2^{nd} channel layers 422 as a 2^{nd} channel structure 422. Further, a space provided by the removal of the 2^{nd} dummy gate structure 450B′ and the 2^{nd} sacrificial layers 421 may be filled in with a metal or a metal alloy to form the 2^{nd} gate structure 450B through, for example, CVD, PVD, atomic layer deposition (ALD), plasma-enhanced ALD (PEALD), etc. or a combination thereof, not being limited thereto.

In this step, an etchant such as HBr/Cl₂/O₂ plasma for dry etching or tetramethylammonium hydroxide (TMAH) for wet etching may be used to remove the 2^{nd} dummy gate structure 450B′ formed of a-Si or p-Si and the 2^{nd} sacrificial layers formed of SiGe against the dummy separation layer 402 and the middle isolation layer 425 formed of SiBCN, SiCN, SiOC, SiOCN, SiN, Si₃N₄, or the like.

Referring to FIG. 5G, a 2^{nd} gate-etch structure 490 may be formed in a space obtained by removing a right portion of the 2^{nd} gate structure 450B including a portion thereof in the non-overlapping region.

To form the 2^{nd} gate-etch structure 490, the right portion of the 2^{nd} gate structure 450B at a right side of the 2^{nd} channel structure 422 may be etched through, for example, dry etching such as reactive ion etching (RIE) from a top surface of the 2^{nd} gate structure 450B down to a top surface of the dummy separation layer 402. Subsequently, an insulation material or a dielectric material such as silicon nitride (e.g., Si₃N₄) may be formed in the space provided by the removal of the right portion of the 2^{nd} gate structure 450B through, for example, PVD, CVD, PECVD, etc., followed by planarization, for example, CMP so that a top surface of the 2^{nd} gate-etch structure 490 may be horizontally coplanar or aligned with the top surface of the 2^{nd} gate structure 450B. The 2^{nd} gate-etch structure 490 may also be formed such that a bottom surface thereof may be at a level below a bottom surface of the lowermost 2^{nd} channel layer 422.

After the formation of the 2^{nd} gate-etch structure 490, at least a portion of the 2^{nd} gate structure including a 2^{nd} work-function metal layer and/or a 2^{nd} gate electrode may remain between the 2^{nd} channel structure and the 2^{nd} gate-etch structure 490 in the D2 direction.

As the 2^{nd} gate-etch structure 490 is formed by removing the right portion of the 2^{nd} gate structure 450B, capacitance generated between the 2^{nd} gate structure 450B and the source/drain regions 413, 423 may be reduced to enhance device performance.

Referring to FIG. 5H, a frontside isolation layer 416 may be formed to surround the 1^{st} channel stack and the 2^{nd} channel structure 422 of the intermediate semiconductor device 40′ and a back end process may be performed to form frontside contact plugs including a gate contact plug 418, via structures and frontside metal lines 419.

The formation of the frontside isolation layer 416 may be performed through, for example, PVD, CVD, PECVD, etc. of a low-k dielectric material such as silicon oxide (e.g., SiO₂), followed by planarization, for example, CMP, not being limited thereto.

The back end process may include dry etching or wet etching of the frontside isolation layer 416 and forming the frontside contact plugs including the gate contact plug 418, the via structures and the frontside metal lines 419 through, for example, PVD, CVD, PECVD, etc. of a metal or a metal alloy.

Referring to FIG. 5I, the substrate 401′ may be removed partially or entirely for a backside process thereafter.

The substrate 401′ may be thinned through, for example, a backside thinning operation in which the substrate 401′ is mechanically grinded to expose the placeholder structure formed to reserve a space for the backside contact plug 404 (FIG. 4B) as described in reference to FIG. 5D, followed by dry etching or wet etching to remove the remaining portion of the substrate 401′ surrounding the placeholder structure.

The substrate removal operation in this step and a subsequent backside process may be performed by flipping upside down the intermediate semiconductor device 40′ obtained in the previous step.

Referring to FIG. 5J, the 1^{st} dummy gate structure 450A′, the 1^{st} sacrificial layers 411 and the dummy separation layer 402 may be removed and replaced by a 1^{st} gate structure 450A so that the 1^{st} channel layers 412 are surrounded by the 1^{st} gate structure 450A.

The 1^{st} dummy gate structure 450A′ and the 1^{st} sacrificial layers 411 may be removed through, for example, dry or wet etching, not being limited thereto, to release the 1^{st} channel layers 422 as a 1^{st} channel structure 422. In addition, the dummy separation layer 402 may be removed using etch selectivity against the middle isolation layer 415. Further, a space provided by the removal of the 1^{st} dummy gate structure 450A′ and the 1^{st} sacrificial layers 411 may be filled in with a metal or a metal alloy to form the 1^{st} gate structure 450A through, for example, ALD, PEALD, CVD, PVD, etc. or a combination thereof, not being limited thereto. Thus, the 1^{st} gate structure 450A and the 2^{nd} gate structure 450B may form a gate structure 450 of the intermediate semiconductor device 40′.

The metal or metal alloy forming a 1^{st} gate electrode of the 1^{st} gate structure 450A may be the same as or different from a 2^{nd} gate electrode forming the 2^{nd} gate structure 450B. However, even if the two gate electrodes of the two gate structures 450A and 450B are formed of the same metal or metal alloy, a connection surface, an interface, or a junction may be formed therebetween because the two gate structure 450A and 450B are formed at different steps and different times.

Referring to FIG. 5K, a 1^{st} gate-etch structure 480 may be formed in a space obtained by removing a left portion of the 1^{st} gate structure 450A and a left portion of the 1^{st} channel structure 412.

To form the 1^{st} gate-etch structure 480, the left portion of the 1^{st} gate structure 450A may be etched through, for example, dry etching such as reactive ion etching (RIE) from a bottom surface of the 1^{st} gate structure 450B to a level of a bottom surface of the middle isolation layer 415 or a level above a top surface of the uppermost 1^{st} channel layer 412. Subsequently, an insulation material or a dielectric material such as silicon nitride (e.g., Si₃N₄) may be formed in the space provided by the removal of the left portion of the 1^{st} gate structure 450A through, for example, PVD, CVD, PECVD, etc., followed by planarization, for example, CMP so that a bottom surface of the 1^{st} gate-etch structure 480 may be horizontally coplanar or aligned with a bottom surface of the 1^{st} gate structure 450A.

In this step, the left portion of the 1^{st} gate structure 450A may be removed such that a left portion of the 1^{st} channel layers 412 may also be removed, and the 1^{st} gate-etch structure 480 may be formed in the space provided by the removal of the left portion of the 1^{st} gate structure 450A such that the 1^{st} gate-etch structure 480 may contact a left side surface of each of the 1^{st} channel layers 412 to be connected thereto in the D2 direction. Thus, a right portion of the 1^{st} gate-etch structure 480 may be vertically overlapped by the middle isolation layer 415 and the 2^{nd} channel layers 422, and further, the 1^{st} gate-etch structure 480 may contact the 1^{st} source/drain regions 413 to be connected thereto in the D1 direction.

As the 1^{st} gate-etch structure 480 is formed in the above manner, an effective channel width (W_{eff}) of a 1^{st} FET to be formed at a 1^{st} level for a stacked semiconductor device may be reduced. Also, a size of the gate structure 450 may also be reduced by the gate-etch structures 480 and 490. Therefore, power consumption of the stacked semiconductor device to be manufactured from the intermediate semiconductor device 40′ may be reduced, thereby achieving a low-power semiconductor device. Further, like the 2^{nd} gate-etch structure 490, the 1^{st} gate-etch structure 480 may also reduce channel resistance or diffusion resistance between the gate structure 450 and the source/drain regions 413 to improve device performance.

It is to be understood here that, in a case where the 1^{st} gate-etch structure 480 is formed in a space obtained by removing a right portion of the 1^{st} gate structure 450A and a right portion of the 1^{st} channel structure 412, the 1^{st} gate-etch structure 480 in the intermediate semiconductor device 40′ shown in FIG. 5K may take a form of the 1^{st} gate-etch structure 380 of the stacked semiconductor device 30 as shown in FIG. 3C.

Referring to FIG. 5L, a backside isolation layer 401 may be formed in a space provided by the removal of the substrate 401′ and a backside contact plug and backside metal lines 409 may be formed in the backside isolation layer 401.

The backside isolation layer 401 may be formed at the space of the removed substrate 401′ through, for example, depositing a low-k material such as silicon oxide (e.g., SiO₂) using CVD, PVD, PECVD, etc., or a combination thereof, not being limited thereto.

Further, the placeholder structure described above in reference to FIGS. 5D and 5I may be removed and the backside contact plug 404 (FIG. 4B) may be formed in a space provided by the removal of the placeholder structure in the backside isolation layer 401, and further, the backside metal lines 409 may be formed to connect the 1^{st} source/drain regions 413 and/or the 2^{nd} source/drain regions 423 to a voltage source of other circuit elements through via structures and the backside contact plug 404.

In the above embodiments, a method of manufacturing the stacked semiconductor device 40 shown in FIG. 4A-4D and an optional method of manufacturing the stacked semiconductor device 30 shown in FIGS. 3A-3D are described in reference to FIGS. 5A-5L. However, the stacked semiconductor device 20 shown in FIGS. 2A-2D may also be manufactured through a similar method except a few steps. For example, the method for manufacturing the stacked semiconductor device 20 may not require formation of the two different dummy gate structures 450A′ and 450B′ with the dummy separation layer 402 therebetween as described in reference to FIG. 5C. Instead, this method may include formation of a single dummy gate structure surrounding the 1^{st} channel stack and the 2^{nd} channel stack in a step corresponding to the step of FIG. 5C and formation of the single gate structure 250 replacing the single dummy gate structure in a step corresponding to FIG. 5F. Further, the gate-etch structure 280 of the stacked semiconductor device 20 may be formed in a frontside process step corresponding to the step of FIG. 5G. Thus, the method of manufacturing the stacked semiconductor device 20 may be more simplified with a more process margin than those for the stacked semiconductor devices 30 and 40.

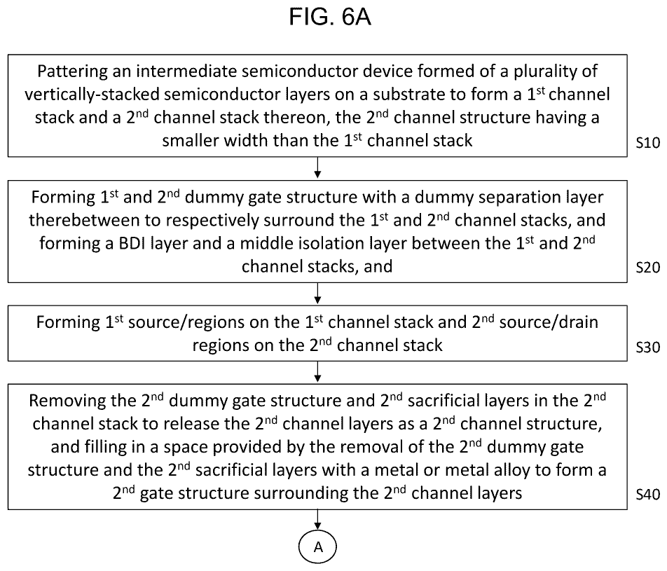

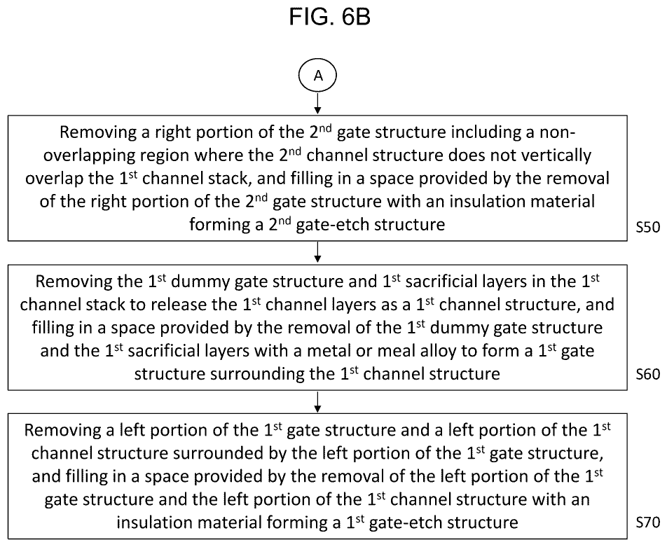

FIGS. 6A and 6B are a flowchart of manufacturing a stacked semiconductor device including gate-etch structures, according to one or more embodiments.

The stacked semiconductor device to be formed through the flowchart of FIGS. 6A and 6B may be the same or similar to the stacked semiconductor device 40 manufactured through steps described above in reference to FIGS. 5A-5L, and thus, duplicate descriptions thereof may be omitted herein.

In step S10, an intermediate semiconductor device formed of a plurality of vertically-stacked semiconductor layers may be provided on a substrate and patterned to form a 1^{st} channel stack and a 2^{nd} channel stack thereon, the 2^{nd} channel structure having a smaller width than the 1^{st} channel stack in the D2 direction such that a right portion of the 1^{st} channel stack is not vertically overlapped by the 2^{nd} channel stack (FIGS. 5A and 5B).

The 1^{st} channel stack and the 2^{nd} channel stack may both be formed of a plurality of sacrificial layers of SiGe and a plurality of channel layers of Si that are alternatingly staked on the substrate. A bottom sacrificial layer may be formed between the substrate and the 1^{st} channel structure, and a middle sacrificial layer may be formed between the 1^{st} channel stack and the 2^{nd} channel stack. The bottom sacrificial layer and the middle sacrificial layer may be formed of SiGe having a higher Ge concentration than the sacrificial layers included in the 1^{st} channel stack and the 2^{nd} channel stack.

In step S20, a 1^{st} dummy gate structure and a 2^{nd} dummy gate structure with a dummy separation layer therebetween may be formed to respectively surround the 1^{st} channel stack and the 2^{nd} channel stack, followed by replacement of the bottom sacrificial layer and the middle sacrificial layer with a BDI layer and a middle isolation layer, respectively (FIG. 5C)

The dummy separation layer may be used in a later step to enable separate formation of a 1^{st} gate structure and a 2^{nd} gate structure replacing the 1^{st} dummy gate structure and the 2^{nd} dummy gate structure, respectively, thereby facilitating separate formation of a 1^{st} gate-etch structure and a 2^{nd} gate-etch structure by removing portions of the 1^{st} gate structure and the 2^{nd} gate structure, respectively.

In step S30, 1^{st} source/drain regions connected through the 1^{st} channel layers in the 1^{st} channel stack and 2^{nd} source/drain regions connected through the 2^{nd} channel layers in the 2^{nd} channel stack may be formed (FIGS. 5D and 5E).

The 1^{st} source/drain regions may be epitaxially grown from the 1^{st} channel layers mainly in the D1 direction, and the 2^{nd} source/drain regions may be epitaxially grown from the 2^{nd} channel layers mainly in the D1 direction. Thus, the 2^{nd} source/drain regions may have a smaller width than the corresponding 1^{st} source/drain regions in the D2 direction, and a right portion of the 1^{st} source/drain regions may not be vertically overlapped by the 2^{nd} source/drain regions, respectively.

In step S40, the 2^{nd} dummy gate structure and the 2^{nd} sacrificial layers in the 2^{nd} channel stack may be removed against the dummy separation layer and the middle isolation layer to release the 2^{nd} channel layers as a 2^{nd} channel structure, and a space provided by the removal of the 2^{nd} dummy gate structure and the 2^{nd} sacrificial layers may be filled in with a metal or metal alloy to form a 2^{nd} gate structure surrounding the 2^{nd} channel structure (FIG. 5F).

In step S50, a right portion of the 2^{nd} gate structure may be removed at a side of the 2^{nd} channel structure which includes a non-overlapping region where the 2^{nd} channel structure does not vertically overlap the 1^{st} channel stack, and a space provided by the removal of the right portion of the 2^{nd} gate structure may be filled in with an insulation material or a dielectric material forming a 2^{nd} gate-etch structure formed (FIG. 5G).

The 2^{nd} gate-etch structure may be formed such that top surfaces of the 2^{nd} gate-etch structure and the 2^{nd} gate structure are horizontally coplanar or aligned with each other and a bottom surface of the 2^{nd} gate-etch structure is at a level below a bottom surface of the lowermost 2^{nd} channel layer or contacts a top surface of the dummy separation layer. Further, the 2^{nd} gate-etch structure may be formed such that a width of the 2^{nd} gate-etch structure is equal to a width of the 2^{nd} gate structure in the D1 direction and a portion of the 2^{nd} gate structure may be formed between the 2^{nd} gate-etch structure and the 2^{nd} channel structure in the D2 direction.

In step S60, the 1^{st} dummy gate structure, the 1^{st} sacrificial layers, and the dummy separation layer may be removed against the 1^{st} gate structure and the middle isolation layer to release the 1^{st} channel layers as a 1^{st} channel structure, and a space provided by the removal of the 1^{st} dummy gate structure, the 1^{st} sacrificial layers and the dummy separation layer may be filled in with a metal or meal alloy to form the 1^{st} gate structure surrounding the 1^{st} channel structure (FIG. 5H-5J)

In step S70, a left portion of the 1^{st} gate structure and a left portion of the 1^{st} channel structure surrounded by the left portion of the 1^{st} gate structure and vertically overlapped by the 2^{nd} channel structure may be removed, and a space provided by the removal of the left portion of the 1^{st} gate structure and the left portion of the 1^{st} channel structure may be filled in with an insulation material or a dielectric material forming a 1^{st} gate-etch structure (FIG. 5K).

The 1^{st} gate-etch structure may be formed such that a top surface of the 1^{st} gate-etch structure contacts a bottom surface of the middle isolation layer or is at a level above a top surface of the uppermost 1^{st} channel layer. Further, the 1^{st} gate-etch structure may be formed to contact a left side surface of the 1^{st} channel structure, for example, left side surfaces of the 1^{st} channel layers, to be connected thereto in the D2 direction. Thus, the 1^{st} gate-etch structure may contact the 1^{st} source/drain regions to be connected thereto in the D1 direction. In addition, a right portion of the 1^{st} gate-etch structure may be vertically overlapped by the 2^{nd} channel structure.

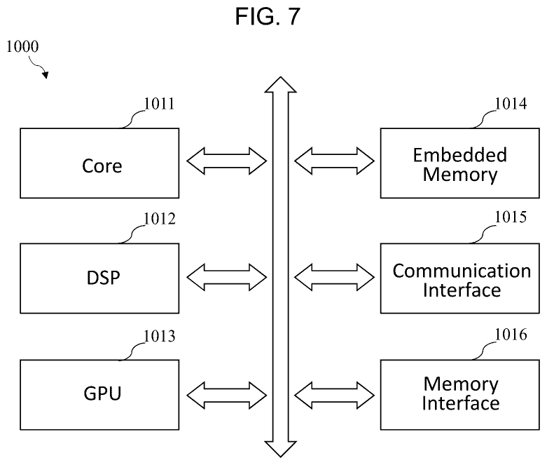

FIG. 7 is a schematic block diagram illustrating an electronic device including one or more stacked semiconductor devices including one or more gate-etch structures, according to one or more embodiments. These stacked semiconductor devices may include one or more of the stacked semiconductor devices 20, 30 and 40 shown in FIGS. 2A-2D, 3A-3D and 4A-4D, respectively.

Referring to FIG. 7, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the stacked semiconductor devices 20, 30 and 40 shown in FIGS. 2A-2D, 3A-3D and 4A-4D, respectively.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a 1^{st} channel structure;
a 1^{st} source/drain region on the 1^{st} channel structure, the 1^{st} source/drain region and the 1^{st} channel structure connected in a 1^{st} direction;
a gate structure on the 1^{st} channel structure; and
a 1^{st} gate-etch structure on the 1^{st} channel structure, the 1^{st} gate-etch structure comprising an insulation material,
wherein the 1^{st} gate-etch structure is connected to the 1^{st} channel structure in a 2^{nd} direction intersecting the 1^{st} direction, and
wherein the 1^{st} gate-etch structure does not extend beyond a length of the 1^{st} channel structure in the 1^{st} direction along a side surface of the 1^{st} source/drain region extending in the 1^{st} direction.

2. The semiconductor device of claim 1, wherein the 1^{st} gate-etch structure contacts the 1^{st} source/drain region to be connected thereto in the 1^{st} direction.

3. The semiconductor device of claim 1, wherein a length of the 1^{st} gate-etch structure is equal to a length of the gate structure in the 1^{st} direction.

4. The semiconductor device of claim 1, further comprising:
a 2^{nd} channel structure above the 1^{st} channel structure in a 3^{rd} direction intersecting the 1^{st} direction and the 2^{nd} direction; and
a 2^{nd} source/drain region on the 2^{nd} channel structure;
wherein the gate structure is on the 2^{nd} channel structure,
wherein the 1^{st} gate-etch structure contacts the gate structure to be connected thereto in the 2^{nd} direction.

5. (canceled)

6. The semiconductor device of claim 4, wherein a portion of the gate structure is between the 2^{nd} channel structure and the 1^{st} gate-etch structure in the 2^{nd} direction.

7. The semiconductor device of claim 6, wherein no portion of the gate structure is between the 1^{st} channel structure and the 1^{st} gate-etch structure in the 2^{nd} direction.

8-10. (canceled)

11. The semiconductor device of claim 1, further comprising:
a 2^{nd} channel structure above the 1^{st} channel structure in a 3^{rd} direction intersecting the 1^{st} direction and the 2^{nd} direction;
a 2^{nd} source/drain region on the 2^{nd} channel structure; and
a 2^{nd} gate-etch structure contacts the gate structure to be connected thereto in the 2^{nd} direction, the 2^{nd} gate-etch structure comprising the insulation material,
wherein the 2^{nd} gate-etch structure and the 1^{st} gate-etch structure are disconnected.

12. (canceled)

13. The semiconductor device of claim 11, wherein a portion of the gate structure is between the 2^{nd} channel structure and the 2^{nd} gate-etch structure in the 2^{nd} direction.

14. The semiconductor device of claim 13, wherein no portion of the gate structure is between the 1^{st} channel structure and the 1^{st} gate-etch structure in the 2^{nd} direction.

15. The semiconductor device of claim 11, wherein the 2^{nd} gate-etch structure is not connected to the 2^{nd} channel structure in the 2^{nd} direction.

16. The semiconductor device of claim 11, wherein an interface or junction is formed between a 1^{st} portion of the gate structure surrounding the 1^{st} channel structure and a 2^{nd} portion of the gate structure surrounding the 2^{nd} channel structure in the 3^{rd} direction.

17. The semiconductor device of claim 11, wherein the 2^{nd} gate-etch structure overlaps the 1^{st} gate-etch structure in the 3^{rd} direction.

18. The semiconductor device of claim 11, wherein the 2^{nd} gate-etch structure does not overlap the 1^{st} gate-etch structure in the 3^{rd} direction.

19-21. (canceled)

22. A semiconductor device comprising:
a 1^{st} channel structure;
a 1^{st} source/drain region on the 1^{st} channel structure, the 1^{st} source/drain region and the 1^{st} channel structure connected in a 1^{st} direction;
a 1^{st} gate structure on the 1^{st} channel structure; and
a 1^{st} gate-etch structure on the 1^{st} channel structure, the 1^{st} gate-etch structure comprising an insulation material,
wherein the 1^{st} gate-etch structure is connected to the 1^{st} channel structure in a 2^{nd} direction intersecting the 1^{st} direction, and
wherein a length of the 1^{st} gate-etch structure is equal to a length of the 1^{st} gate structure in the 1^{st} direction.

23. The semiconductor device of claim 22, wherein the length of the 1^{st} gate-etch structure is equal to a length of a 1^{st} channel structure in the 1^{st} direction.

24-26. (canceled)

27. The semiconductor device of claim 22, wherein two side surfaces of the 1^{st} gate-etch structure opposite in the 1^{st} direction is coplanar or aligned with two side surface of the 1^{st} channel structure opposite in the 1^{st} direction.

28-31. (canceled)

32. A semiconductor device comprising:
a 1^{st} gate structure and a 2^{nd} gate structure adjacent thereto in a 1^{st} direction, the 1^{st} gate structure and the 2^{nd} gate structure extending in a 2^{nd} direction that intersects the 1^{st} direction;
a source/drain region between the 1^{st} gate structure and the 2^{nd} gate structure; and
a gate-etch structure on the 1^{st} gate structure among the 1^{st} gate structure and the 2^{nd} gate structure, the gate-etch structure comprising an insulation material.

33. The semiconductor device of claim 32, wherein the 1^{st} gate structure has a smaller width than the 2^{nd} gate structure in the 2^{nd} direction.

34. The semiconductor device of claim 32, further comprising a channel structure,
wherein the gate-etch structure contacts a side surface of the channel structure to be connected thereto in the 2^{nd} direction.

35. The semiconductor device of claim 32, wherein the gate-etch structure contacts the source/drain region to be connected thereto in the 1^{st} direction.

36-44. (canceled)
